(19) United States
(12) Patent Application Publication
(10) Pub. No.: US 2016/0273564 A1
(43) Pub. Date: Sep. 22, 2016

(54) SUB-FLUSH CIRCUIT BOARD MOUNTING SCREW

(71) Applicant: MICROSOFT TECHNOLOGY LICENSING, LLC, Redmond, WA (US)

(72) Inventors: James Michael BONICATTO, Seattle, WA (US); Andrew William HILL, Redmond, WA (US); Nathan Michael THOME, Seattle, WA (US); John GODFREY, Woodinville, WA (US); Robyn MCLAUGHLIN, Seattle, WA (US); Santosh SHETTY, Redmond, WA (US)

(21) Appl. No.: 14/664,391

(22) Filed: Mar. 20, 2015

(51) Int. Cl. F16B 5/00; H05K 7/14; H05K 13/00

(52) U.S. Cl. CPC F16B 5/00; H05K 13/0023; H05K 7/1407

(57) ABSTRACT

Examples of the disclosure enable a printed circuit board to be coupled to a chassis. In some examples, a coupling mechanism includes a first body including a head portion and a shaft portion that has an inner surface defining a channel. The coupling mechanism includes a second body including a head portion and a shaft portion. At least a part of the second body shaft portion is positionable within the channel. An outer surface of the second body shaft portion is sized to enable the second body shaft portion to expand radially or move laterally within the channel when the part of the second shaft portion is positioned within the channel. Examples of the disclosure enable the printed circuit board to be coupled to a chassis in low-profile, reduced-stress manner.

### BRIEF DESCRIPTION OF THE DRAWINGS

FIG. 1 is a cross-sectional perspective view of an example system including a printed circuit board and a coupling mechanism configured to couple the printed circuit board to an article.

FIG. 2 is a cross-sectional plan view of the system shown in FIG. 1.

FIG. 3 is a perspective view of an example housing mechanism that may be used with a coupling mechanism, such as the coupling mechanism shown in FIGS. 1 and 2.

FIG. 4 is a plan view of the housing mechanism shown in FIG. 3.

FIG. 5 is a perspective view of another example housing mechanism that may be used with a coupling mechanism, such as the coupling mechanism shown in FIGS. 1 and 2.

FIG. 6 is a cross-sectional plan view of the housing mechanism shown in FIG. 5.

FIG. 7 is a perspective view of yet another example housing mechanism that may be used with a coupling mechanism, such as the coupling mechanism shown in FIGS. 1 and 2.

FIG. 8 is a plan view of the housing mechanism shown in FIG. 7.

FIG. 9 is a perspective view of yet another example housing mechanism that may be used with a coupling mechanism, such as the coupling mechanism shown in FIGS. 1 and 2.

FIG. 10 is a cross-sectional plan view of the housing mechanism shown in FIG. 9.

FIG. 11 is a cross-sectional plan view of another example system including a printed circuit board and a coupling mechanism configured to couple the printed circuit board to an article.

FIG. 12 is a cross-sectional plan view of yet another example system including a printed circuit board and a coupling mechanism configured to couple the printed circuit board to an article.

FIG. 13 is a cross-sectional plan view of yet another example system including a printed circuit board and a coupling mechanism configured to couple the printed circuit board to an article.

FIGS. 14 and 15 are perspective views of yet another example system including a printed circuit board and a coupling mechanism configured to couple the printed circuit board to an article.

FIG. 16 is a flow chart illustrating an example method of coupling a printed circuit board to an article using a coupling mechanism.

Corresponding reference characters indicate corresponding parts throughout the drawings.

### DETAILED DESCRIPTION

With the increased demand for portable computing devices, such as laptops, smartphones, tablets, and/or phablets, at least some computing devices have become thinner to increase a portability of the computing device. Known methods and systems for manufacturing and/or producing thinner computing devices are somewhat restricted by current infrastructure (e.g., hardware requirements). In addition to printed circuit boards and/or other electronic devices, computing devices are designed to accommodate fastening mechanisms (e.g., screws, rivets) that couple electronic devices to a chassis and/or frame.

At least some known computing devices include a printed circuit board having an opening, and a coupling mechanism including a shaft portion extending through the opening and a head portion positioned above an upper surface of the printed circuit board, which may increase a height of at least a part of the computing device. To accommodate the head portion of the coupling mechanism and/or decrease the height of at least the part of the computing device, at least some known computing devices include a printed circuit board having an opening sized to receive the head portion using a countersink configuration. However, such printed circuit boards may not allow for much thermal expansion of the coupling mechanism and/or allocation for lateral tolerances. Additionally or alternatively, such printed circuit boards are subjected to lateral stress induced from the head portion of the coupling mechanism, which may distort at least a part of the printed circuit board over time and/or with continued use.

Examples of the disclosure enable a printed circuit board to be coupled to a chassis. Some examples include a coupling mechanism including an insert and/or housing mechanism at least partially positionable within an opening defined by a printed circuit board, and a mounting screw and/or fastening mechanism at least partially positionable within a channel defined by the insert shaft portion such that the printed circuit board is coupled to the chassis.

Aspects of the disclosure enable a printed circuit board to be coupled to a chassis, such that a coupling mechanism that couples the printed circuit board to the chassis lies flush or below (“sub-flush”) an upper surface of the printed circuit board. By incorporating the coupling mechanism in the manner described in this disclosure, some examples enable miniaturization, e.g., require less space for functionality, improved usability, and/or enhanced reliability of a device.

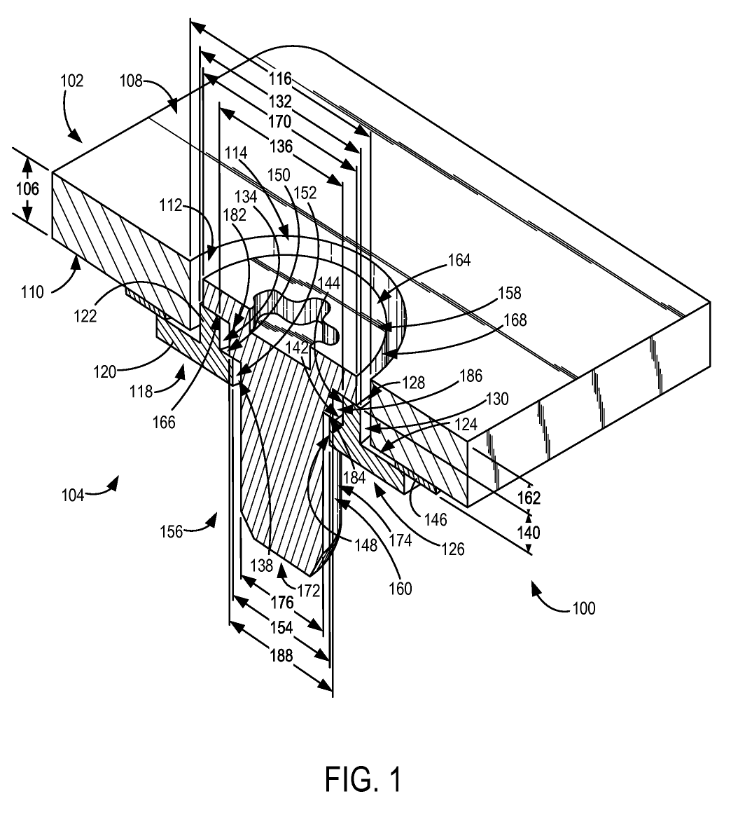

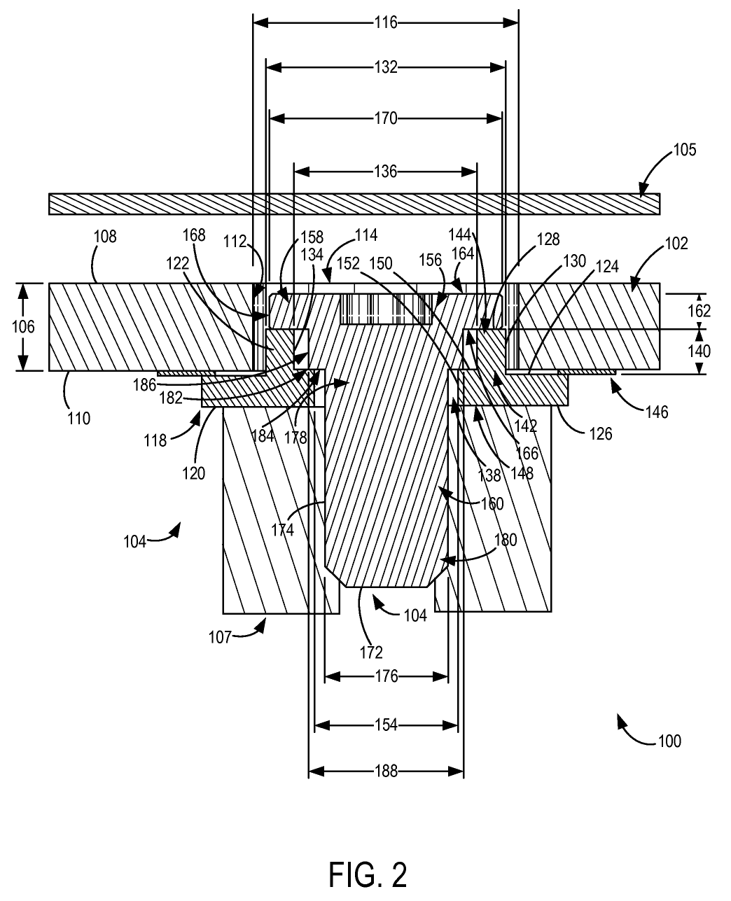

FIG. 1 is a cross-sectional perspective view of an example system 100 including one or more printed circuit boards (PCBs) 102 (or other relatively thin body to be coupled to another body) and a coupling mechanism 104 configured to couple the one or more PCBs 102 to a chassis, frame, body, and/or article (not shown in FIG. 1). For example, the system 100 may be used with a touchscreen device. FIG. 2 is a cross-sectional plan view of the system 100 including a cover 105 (e.g., a cover glass) positioned and/or extending above the system 100 and a chassis 107 below the system 100. In this example, the PCB 102 is substantially planar and/or flat. Alternatively, the PCB 102 may be curved and/or contoured.

The PCB 102 has a thickness or height 106 extending between an upper surface 108 and a lower surface 110. The height 106 is sized to receive at least a part of the coupling mechanism 104. The PCB 102 has an inner surface 112 that defines an opening 114 extending through the PCB 102 between the upper surface 108 and the lower surface 110. The inner surface 112 has an inner diameter 116 sized to receive at least a part of the coupling mechanism 104. In one example, the inner diameter 116 is between approximately 2.62 mm and approximately 2.78 mm. Alternatively, the inner surface 112 may have any diameter that enables the PCB 102 to function as described herein.

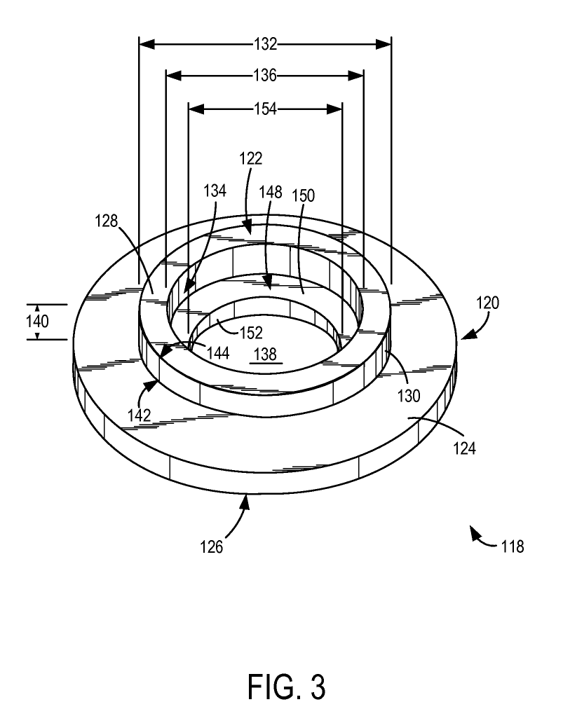

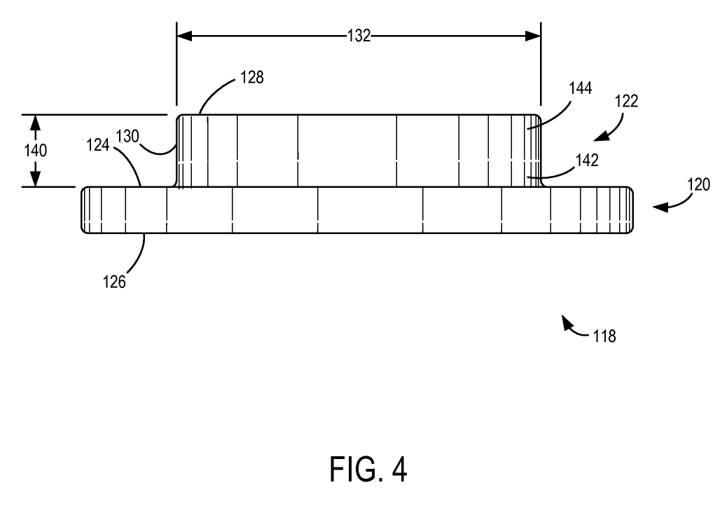

The coupling mechanism 104 includes an insert or housing mechanism 118 (e.g., a first body) including a head portion 120 (e.g., washer) and a shaft portion 122 (e.g., collar) extending from the head portion 120. FIG. 3 is a perspective view of the housing mechanism 118. FIG. 4 is a plan view of the housing mechanism 118. The head portion 120 has an upper surface 124 and a lower surface 126. In one example, the thickness or height between the upper surface 124 and the lower surface 126 is approximately 0.25 mm and approximately 0.35 mm. Additionally or alternatively, the head portion 120 has an outer diameter between approximately 3.50 mm and approximately 3.70 mm. Alternatively, the head portion 120 may have any height and/or diameter that enables the housing mechanism 118 to function as described herein.

The shaft portion 122 has an upper surface 128, an outer surface 130 having an outer diameter 132 (e.g., a first diameter) sized to fit within the opening 114 (e.g., the outer diameter 132 is less than or equal to the inner diameter 116 of the PCB 102), and a first inner surface 134 (not shown in FIG. 4) having an inner diameter 136 (not shown in FIG. 4). In one example, the outer diameter 132 is between approximately 2.41 mm and approximately 2.51 mm. Additionally or alternatively, the inner diameter 136 is between approximately 1.72 mm and approximately 1.88 mm. Alternatively, the shaft portion 122 may have any diameter that enables the housing mechanism 118 to function as described herein.

The first inner surface 134 at least partially defines a channel 138 (not shown in FIG. 4) extending through the housing mechanism 118 between the lower surface 126 of the head portion 120 and the upper surface 128 of the shaft portion 122. The shaft portion 122 has a depth or height 140 extending between a first end section 142 coupled to the head portion 120, and a second end section 144 opposite the first end section 142. In one example, the height 140 is between approximately 0.35 mm and approximately 0.50 mm. Alternatively, the shaft portion 122 may have any height that enables the housing mechanism 118 to function as described herein.

In some examples, the housing mechanism 118 is coupleable to the lower surface 110 of the PCB 102 such that the shaft portion 122 is positioned and/or extends at least partially through the opening 114. In at least some examples, the head portion 120 is sized such that the housing mechanism 118 does not fully traverse and/or pass through the PCB 102. For example, the upper surface 124 of the head portion 120 may engage the lower surface 110 of the PCB 102 when inserting the housing mechanism 118 into the opening 114.

In at least some examples, the upper surface 124 of the head portion 120 faces and/or extends substantially parallel to the lower surface 110 of the PCB 102 when the housing mechanism 118 is coupled to the PCB 102. Additionally or alternatively, the outer surface 130 of the shaft portion 122 faces and/or extends substantially parallel to the inner surface 112 of the PCB 102 when the housing mechanism 118 is coupled to the PCB 102.

In at least some examples, a soldering material 146 (shown in FIGS. 1 and 2) is between the upper surface 124 of the head portion 120 and the lower surface 110 of the PCB 102 and/or the outer surface 130 of the shaft portion 122 and the inner surface 112 of the PCB 102. In one example, a pad of the soldering material 146 may have a diameter of at least approximately 4.0 mm. Alternatively, the pad of the soldering material 146 may have any diameter that enables the PCB 102 and/or housing mechanism 118 to function as described herein. The soldering material 146 facilitates maintaining a relative positioning of the PCB 102 and/or the housing mechanism 118. Alternatively, the housing mechanism 118 is coupled to the PCB 102 with a mechanical press and/or compression fit.

In some examples, the housing mechanism 118 includes a shoulder portion 148 (not shown in FIG. 4) extending radially inward from the head portion 120 and/or shaft portion 122. In at least some examples, the shoulder portion 148 includes an upper surface 150 (not shown in FIG. 4) and a second inner surface 152 (not shown in FIG. 4) radially inward of the first inner surface 134 and having an inner diameter 154 (not shown in FIG. 4). In at least some examples, the second inner surface 152 at least partially defines the channel 138 extending through the housing mechanism 118 between the lower surface 126 of the head portion 120 and the upper surface 128 of the shaft portion 122. In one example, the inner diameter 154 is between approximately 1.32 mm and approximately 1.48 mm. Alternatively, the inner surface 152 may have any diameter that enables the housing mechanism 118 to function as described herein.

Referring again to FIGS. 1 and 2, the coupling mechanism 104 includes a screw or fastening mechanism 156 (e.g., a second body) including a head portion 158 and a shaft portion 160 extending from the head portion 158. The fastening mechanism 156 may be any mechanism that is configured to couple the system 100 to the chassis 107. For example, the fastening mechanism 156 may be a rivet used to couple the PCB 102 to the chassis 107 a single time and/or the fastening mechanism 156 may be a screw used to couple (and/or or uncouple) the PCB 102 to (and/or from) the chassis 107 one or more times. The head portion 158 has a thickness or height 162 extending between an upper surface 164 and a lower surface 166 and sized such that a combined height of the height 162 and the height 140 of the shaft portion 122 is less than or equal to the height 106 of the PCB 102.

In one example, the fastening mechanism 156 is a rivet. In this example, the fastening mechanism 156, being a rivet, couples the PCB 102 to the chassis 107 when the rivet is driven through the housing mechanism 118 and is forced and implanted in to the chassis 107. The advantage of this system is that the housing mechanism 118 mechanically stabilizes and supports the force of the fastening mechanism 156 on the PCB 102 while permitting the fastening mechanism to be sub-flush with the PCB 102. In another example, the fastening mechanism 156 is a screw that includes threading on the shaft portion 160. The chassis 107 may include a threaded hole that accepts the threading on the shaft portion 160 of fastening mechanism 156. In this manner, the fastening mechanism 156 screws into the chassis 107, thereby providing the advantage that the PCB 102 may be unscrewed and removed from the chassis 107 to permit maintenance or repair of the PCB 102, the chassis 107, or another component of the device.

The head portion 158 has an outer surface 168 having an outer diameter 170 (e.g., a second diameter) sized to fit within the opening 114 while providing at least some vertical support to the fastening mechanism 156 (e.g., the outer diameter 170 is less than or equal to the inner diameter 116 of the PCB 102 and greater than the first inner diameter 136 of the housing mechanism 118). In at least some examples, the outer diameter 170 is less than or equal to the outer diameter 132 of the housing mechanism shaft portion 122.

The shaft portion 160 has a lower surface 172, and a first outer surface 174 having an outer diameter 176 sized to fit within the channel 138 (e.g., the outer diameter 176 is less than or equal to the inner diameters 136 and/or 154 of the housing mechanism 118). The shaft portion 160 has a first end section 178 (shown in FIG. 2) coupled to the head portion 158, and a second end section 180 (shown in FIG. 2) opposite the first end section 178.

In some examples, the fastening mechanism 156 is configured to engage the housing mechanism 118 such that at least a part of the shaft portion 160 is positioned and/or extends through the channel 138. In at least some examples, the head portion 158 is sized such that the fastening mechanism 156 does not directly interface with the PCB 102 and such that the fastening mechanism 156 does not fully traverse and/or pass through the housing mechanism 118. For example, the lower surface 166 of the head portion 158 may engage the upper surface 128 of the housing mechanism shaft portion 122 when inserting the fastening mechanism 156 into the channel 138.

In at least some examples, the lower surface 166 of the head portion 158 faces and/or extends substantially parallel to the upper surface 128 of the housing mechanism shaft portion 122 when the fastening mechanism 156 engages the housing mechanism 118. In at least some examples, the head portion 158 engages the housing mechanism shaft portion 122 such that the upper surface 164 of the head portion 158 is below or flush with the PCB upper surface 108.

Additionally or alternatively, the first outer surface 174 of the shaft portion 160 faces and/or extends substantially parallel to the first inner surface 134 of the housing mechanism shaft portion 122 and/or the second inner surface 152 of the housing mechanism shoulder portion 148 when the fastening mechanism 156 engages the housing mechanism 118. In at least some examples, the shaft portion 160 is sized to expand and/or contract radially and/or move laterally within the channel 138 when at least the part of the shaft portion 160 is positioned and/or extends through the channel 138.

In some examples, the fastening mechanism 156 includes a shoulder portion 182 between the head portion 158 and the shaft portion 160. In at least some examples, the shoulder portion 182 includes a lower surface 184 and a second outer surface 186 radially outward of the first outer surface 174 and having an outer diameter 188 sized to fit within the channel 138 while providing at least some vertical support to the fastening mechanism 156 (e.g., the outer diameter 188 is less than or equal to the first inner diameter 136 of the housing mechanism 118 and greater than or equal to the second inner diameter 154 of the housing mechanism 118).

In some examples, the fastening mechanism 156 is configured to engage the housing mechanism 118 such that the shoulder portion 182 is positioned and/or extends at least partially through the channel 138. In at least some examples, the shoulder portions 148 and/or 182 are sized such that the fastening mechanism 156 does not fully traverse and/or pass through the housing mechanism 118. For example, the lower surface 184 of the fastening mechanism shoulder portion 182 may engage the upper surface 150 of the housing mechanism 148 when inserting the fastening mechanism 156 into the channel 138.

In at least some examples, the lower surface 184 of the fastening mechanism shoulder portion 182 faces and/or extends substantially parallel to the upper surface 150 of the housing mechanism shoulder portion 148 when the fastening mechanism 156 engages the housing mechanism 118. Additionally or alternatively, the second outer surface 186 of the fastening mechanism shoulder portion 182 faces and/or extends substantially parallel to the first inner surface 134 of the housing mechanism shaft portion 122 when the fastening mechanism 156 engages the housing mechanism 118. In at least some examples, the shoulder portion 182 is sized to expand and/or contract radially and/or move laterally within the channel 138 when at least the part of the shoulder portion 182 is positioned and/or extends through the channel 138.

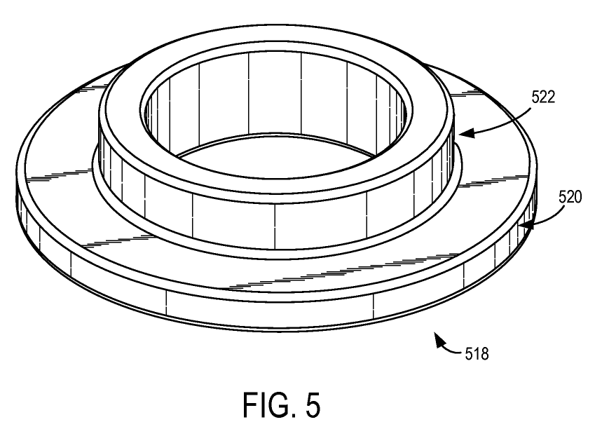

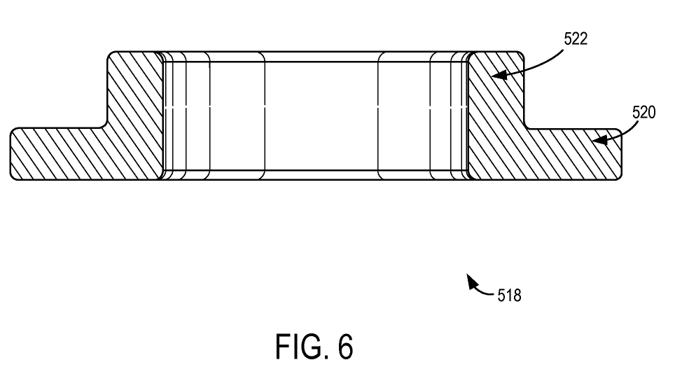

FIG. 5 is a perspective view of another example housing mechanism 518 that may be used with the PCB 102 and/or fastening mechanism 156. FIG. 6 is a cross-sectional plan view of the housing mechanism 518. Similar to housing mechanism 118, the housing mechanism 518 includes a head portion 520 and a shaft portion 522. The head portion 520 and/or shaft portion 522 are substantially similar to the head portion 120 and/or shaft portion 122, respectively, of the housing mechanism 118, with like elements having like numbers. Unlike housing mechanism 118, the housing mechanism 718 does not include a shoulder portion.

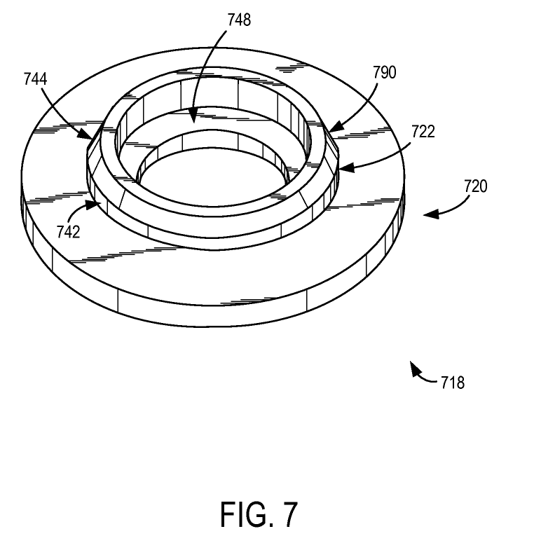

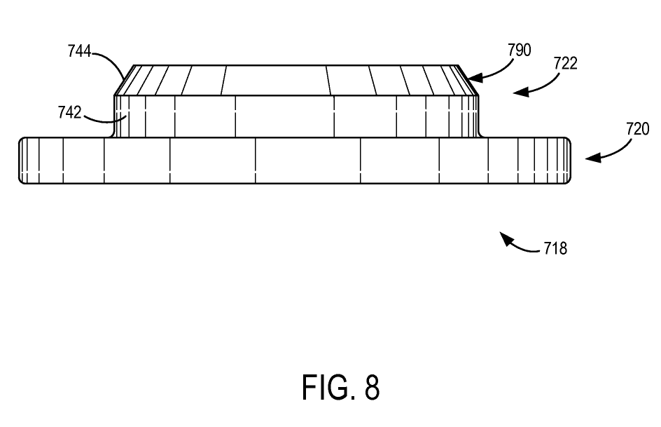

FIG. 7 is a perspective view of another example housing mechanism 718 that may be used with the PCB 102 and/or fastening mechanism 156. FIG. 8 is a plan view of the housing mechanism 718. Similar to housing mechanism 118, the housing mechanism 718 includes a head portion 720, a shaft portion 722, and a shoulder portion 748 (not shown in FIG. 7). The head portion 720, shaft portion 722, and/or shoulder portion 748 are substantially similar to the head portion 120, shaft portion 122, and/or shoulder portion 148, respectively, of the housing mechanism 118, with like elements having like numbers.

In some examples, the shaft portion 722 has a first end section 742 coupled to the head portion 720, and a second end section 744 opposite the first end section 742. In some examples, the second end section 744 includes and/or has a chamfer 790. In at least some examples, chamfer 790 at least partially defines a chamber or cavity between the shaft portion 722 and the PCB 102 that is configured to retain soldering material (shown in FIGS. 1 and 2) between the outer surface 730 of the shaft portion 722 and the PCB inner surface 112 (shown in FIGS. 1 and 2). Alternatively, the shaft portion 722 may include an edge cut, corner relief, notch, valley, and/or cutaway having any shape at any section of the shaft portion 722 that enables the housing mechanism 718 to function as described herein.

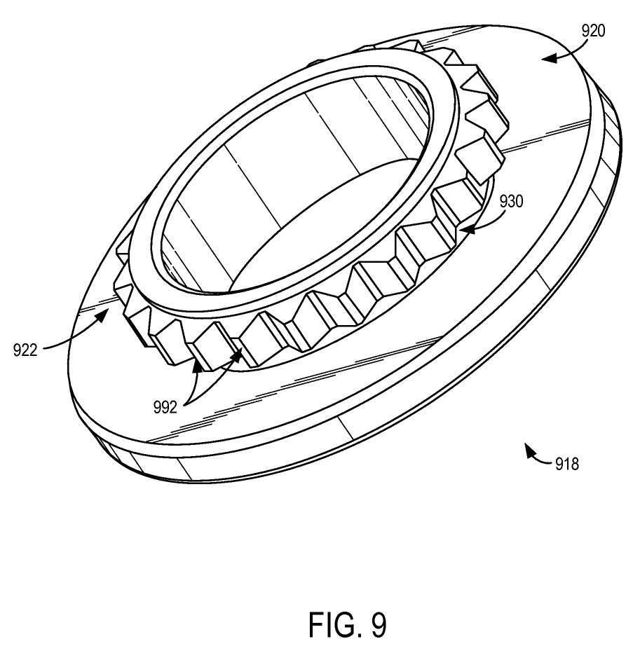

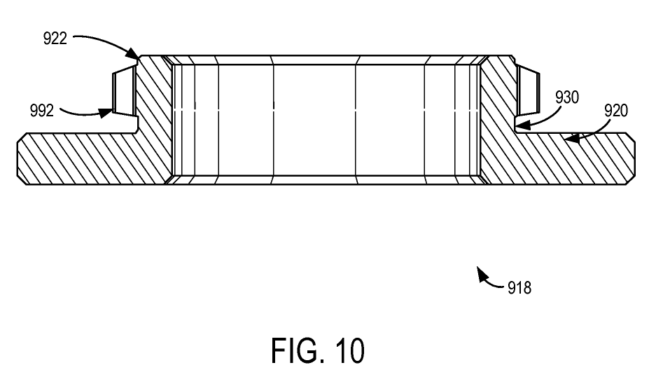

FIG. 9 is a perspective view of another example housing mechanism 918 that may be used with the PCB 102 and/or fastening mechanism 156. FIG. 10 is a cross-sectional plan view of the housing mechanism 918. Similar to housing mechanism 118, the housing mechanism 918 includes a head portion 920 and/or a shaft portion 922. The head portion 920 and/or shaft portion 922 are substantially similar to the head portion 120 and/or shaft portion 122, respectively, of the housing mechanism 118, with like elements having like numbers. Unlike housing mechanism 118, the housing mechanism 918 does not include a shoulder portion.

In some examples, the shaft portion 922 has an outer surface 930 and a plurality of projection members 992 extending radially outward from the outer surface 930. In at least some examples, a chamber or cavity is defined between adjacent projection members 930 and the PCB 102 and/or between a projection member 930 and the head portion 920 that are configured to retain soldering material (shown in FIGS. 1 and 2) between the outer surface 930 of the shaft portion 922 and the PCB inner surface 112 (shown in FIGS. 1 and 2). Alternatively, the shaft portion 922 may include an edge cut, corner relief, notch, valley, and/or cutaway having any shape at any section of the shaft portion 922 that enables the housing mechanism 918 to function as described herein.

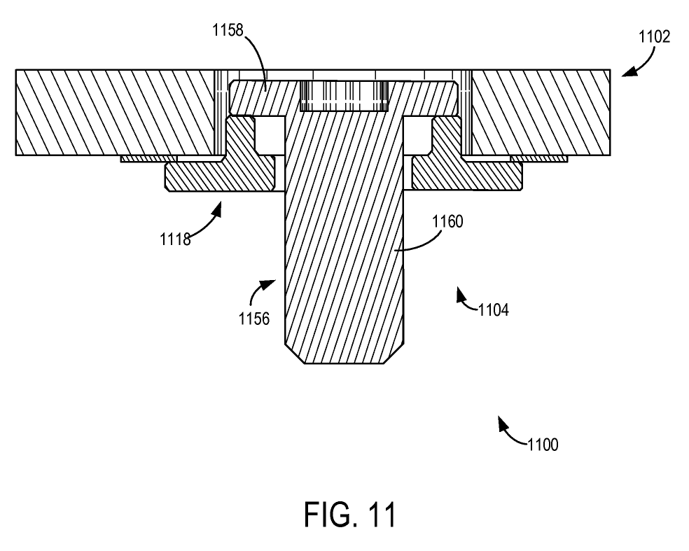

FIG. 11 is a cross-sectional plan view of a system 1100 including a printed circuit board (PCB) 1102 and a coupling mechanism 1104 configured to couple the PCB 1102 to a chassis 107 (not shown). Similar to coupling mechanism 104, the coupling mechanism 1104 includes a housing mechanism 1118 and a fastening mechanism 1156. The PCB 1102, housing mechanism 1118, and/or fastening mechanism 1156 are substantially similar to the PCB 102, housing mechanism 118, and/or fastening mechanism 156, respectively, of the system 100, with like elements having like numbers. The fastening mechanism 1156 includes a head portion 1158 and a shaft portion 1160 extending from the head portion 1158. Unlike fastening mechanism 156, the fastening mechanism 1156 does not include a shoulder portion.

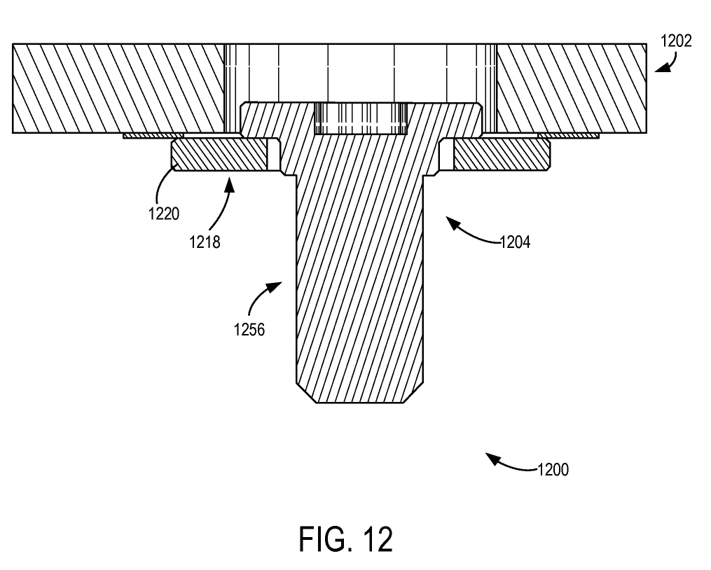

FIG. 12 is a cross-sectional plan view of a system 1200 including a printed circuit board (PCB) 1202 and a coupling mechanism 1204 configured to couple the PCB 1202 to a chassis 107 (not shown). Similar to coupling mechanism 104, the coupling mechanism 1204 includes a housing mechanism 1218 and a fastening mechanism 1256. The PCB 1202, housing mechanism 1218, and/or fastening mechanism 1256 are substantially similar to the PCB 102, housing mechanism 118, and/or fastening mechanism 156, respectively, of the system 100, with like elements having like numbers. The housing mechanism 1218 includes a head portion 1220. Unlike housing mechanism 118, the housing mechanism 1218 does not include a shaft portion and/or a shoulder portion.

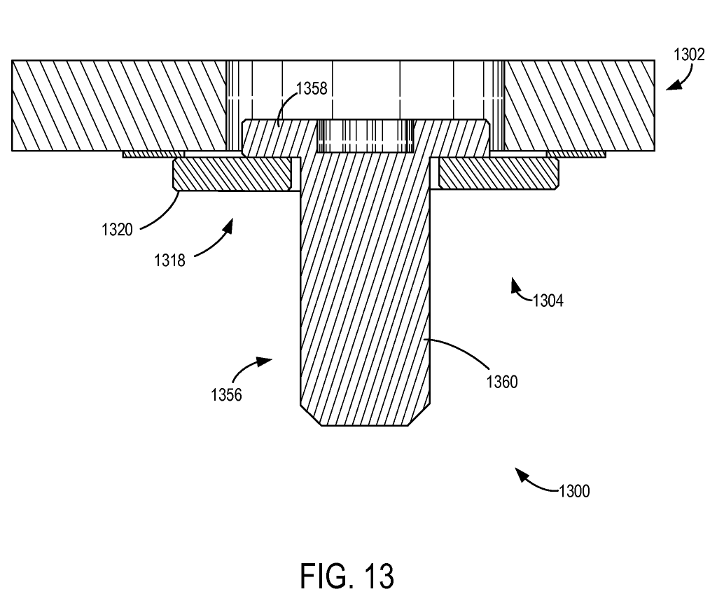

FIG. 13 is a cross-sectional plan view of a system 1300 including a printed circuit board (PCB) 1302 and a coupling mechanism 1304 configured to couple the PCB 1302 to a chassis 107 (not shown). Similar to coupling mechanism 104, the coupling mechanism 1304 includes a housing mechanism 1318 and a fastening mechanism 1356. The PCB 1302, housing mechanism 1318, and/or fastening mechanism 1356 are substantially similar to the PCB 102, housing mechanism 118, and/or fastening mechanism 156, respectively, of the system 100, with like elements having like numbers. The housing mechanism 1318 includes a head portion 1320. Unlike housing mechanism 118, the housing mechanism 1318 does not include a shaft portion and/or a shoulder portion. The fastening mechanism 1356 includes a head portion 1358 and a shaft portion 1360 extending from the head portion 1358. Unlike fastening mechanism 156, the fastening mechanism 1356 does not include a shoulder portion.

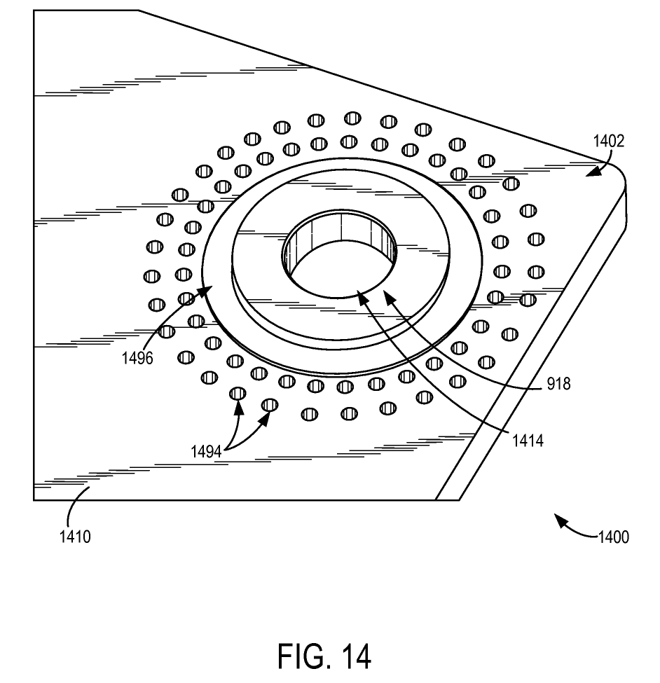

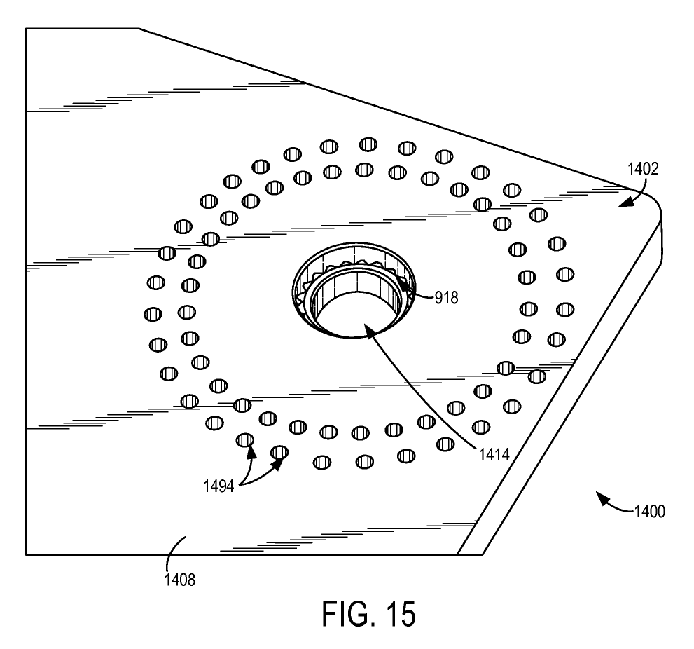

FIG. 14 is a perspective view of a lower side of a system 1400 including a printed circuit board (PCB) 1402 and the housing mechanism 918. FIG. 15 is a perspective view of an upper side of the system 1400. Similar to PCB 102, the PCB 1402 has an upper surface 1408 (shown in FIG. 15) and a lower surface 1410 (shown in FIG. 14). The PCB 1402 is substantially similar to the PCB 102 of the system 100, with like elements having like numbers. The PCB 1402 includes an opening 1414 extending through the PCB 1402 between the upper surface 1408 and the lower surface 1410. Unlike PCB 102, the PCB 1402 includes a plurality of vias 1494 extending through the PCB 1402 between the upper surface 1408 and the lower surface 1410.

In some examples, the vias 1494 enable increasing a load and/or strength associated with the PCB 1402. In at least some examples, one or more vias 1494 include and/or have a respective component (e.g., a metal barrel) extending through the via 1494. In at least some examples, the components at least partially reinforce a layer (e.g., an epoxy matrix) of and/or associated with the PCB 1402. For example, the components are configured to at least partially reinforce an epoxy matrix to reduce a probability of the epoxy matrix delaminating. In this example, the vias 1494 extend perpendicular and/or substantially perpendicular to the upper surface 1408 and/or lower surface 1410. Alternatively, the vias 1494 may be aligned and/or oriented in any direction that enables the PCB 1402 to function as described herein.

The vias 1494 may be arranged about the PCB 1402 in a predetermined pattern. For example, the vias 1494 may be arranged in a symmetrical pattern (e.g., a pattern having reflection symmetry, rotation symmetry, and/or translation symmetry). In this example, the vias 1494 are arranged in a radial pattern about the opening 1414. More specifically, in this example, the vias 1494 are oriented to be perpendicular to the upper surface 1408 and the lower surface 1410, and are arranged in a symmetrical pattern, such that the arrangement of the vias 1494 appears to be the same, similar, and/or substantially similar when viewed from the lower side (see, e.g., FIG. 14) or the upper side (see, e.g., FIG. 15). Alternatively, the vias 1494 may be arranged in any configuration that enables the PCB 1402 to function as described herein.

In some examples, the system 1400 includes a frame and/or stencil 1496 (shown in FIG. 14) that enables a soldering material (e.g., soldering material 146) to be applied and/or positioned on the PCB 1402 in a desired pattern and/or configuration. In some examples, the stencil 1496 is configured to enable the soldering material to cover a desired area without flowing on “top” of the coupling mechanism 104 (e.g., below the lower surface 126 of the housing mechanism head portion 120 and/or above the upper surface 164 of the fastening mechanism head portion 158). In this example, the stencil 1496 is sized, shaped, and/or configured to enable the soldering material to be applied in a radial pattern about the opening 1414. Alternatively, the stencil 1496 may have any configuration that enables the PCB 1402 to function as described herein.

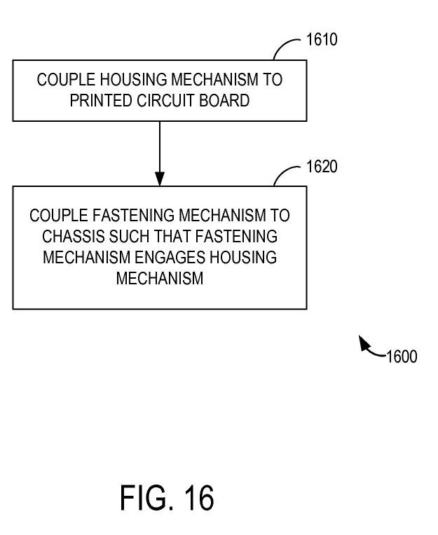

FIG. 16 is a flow chart illustrating an example method 1600 of coupling a PCB (e.g., PCB 102, 1102, 1202, 1302, 1402) to a chassis 107 using a coupling mechanism (e.g., coupling mechanism 104, 1104, 1204, 1304).

In some examples, a housing mechanism (e.g., housing mechanism 118, 518, 718, 918, 1118, 1218, 1318) is coupled to the printed circuit board (PCB) 102 at 1610. In at least some examples, the housing mechanism 118 is positioned such that an upper surface 124 of a head portion 120 of the housing mechanism 118 extends substantially parallel to a lower surface 110 of the PCB 102. In at least some examples, the housing mechanism 118 is coupled to the lower surface 110 of the PCB 102 such that the head portion 120 of the housing mechanism 118 engages the lower surface 110 of the PCB 102, and/or a shaft portion 112 of the housing mechanism 118 extends at least partially through an opening 114 defined in the PCB 102.

In at least some examples, the housing mechanism 118 is soldered to the lower surface 110 of the PCB 102 using a soldering material 146. In at least some examples, the soldering material 146 is applied such that the soldering material 146 is between the upper surface 124 of the head portion 120 and the lower surface 110 of the PCB 102 and/or the outer surface 130 of the shaft portion 122 and the inner surface 112 of the PCB 102. In at least some examples, at least a portion of the soldering material 146 is within a cavity at least partially defined by a chamfer 790 of the housing mechanism 118. Alternatively, the soldering material 146 may be applied in any position that enables the system 100 to function as described herein.

In some examples, a fastening mechanism 156 is coupled to the chassis 107 at 1620. In at least some examples, the fastening mechanism 156 is positioned such that an outer surface 174 of a shaft portion 160 of the fastening mechanism 156 extends substantially parallel to the inner surface 134 of the housing mechanism shaft portion 112. Additionally or alternatively, the fastening mechanism 156 is positioned such that an upper surface 164 of a head portion 158 of the fastening mechanism 156 is below or flush with an upper surface 108 of the PCB 102 to facilitate reducing and/or controlling a thickness of the system 100 and/or reducing protrusions (or opportunities for protrusions) that may occur on the cover 105 used with the system 100 when the cover 105 is compressed onto the system 100 during use.

In at least some examples, the fastening mechanism 156 is coupled to the chassis 107 such that a head portion 158 of the fastening mechanism 156 engages an upper surface of the shaft portion 112 of the housing mechanism 118, and at least a part of the shaft portion 160 of the fastening mechanism 156 extends through a channel 138 defined by the housing mechanism 118. In at least some examples, the fastening mechanism 156 is positioned such that a shoulder portion 182 of the fastening mechanism 156 engages a shoulder portion 146 of the housing mechanism 118.

In at least some examples, the shaft portion 112 of the housing mechanism 118 and/or the channel 138 are sized such that the shaft portion 112 may expand and/or contract radially and/or move laterally within the channel 138. For example, the fastening mechanism 156 may expand and/or contract during operation and/or use of a computing device 100 in which the system 100 is included due to increased temperatures. For another example, the housing mechanism 118 may be configured to accommodate for lateral tolerances (e.g., components within the system 100 shifting laterally). For yet another example, the housing mechanism 118 may be configured to accommodate for part tolerances (e.g., components within the system 100 may not be manufactured and/or fabricated to specification).

The subject matter described herein enables a component (e.g., printed circuit board) to be coupled to a chassis. In some examples, an insert and/or housing mechanism is used to accommodate a screw and/or fastening mechanism such that a head of the fastening mechanism is flush with and/or below an upper surface of the component and/or a shaft of the fastening mechanism is allowed to expand, contract, and/or laterally move within the housing mechanism. In this way, the component may maintain a low profile and/or be exposed to a reduced amount of pressure and/or stress.

Although described in connection with an example computing system environment, examples of the disclosure are capable of implementation with numerous other general purpose or special purpose computing system environments, configurations, or devices.

Examples of well-known computing systems, environments, and/or configurations that may be suitable for use with aspects of the disclosure include, but are not limited to, mobile computing devices, personal computers, server computers, hand-held or laptop devices, multiprocessor systems, gaming consoles, microprocessor-based systems, set top boxes, programmable consumer electronics, mobile telephones, mobile computing and/or communication devices in wearable or accessory form factors (e.g., watches, glasses, headsets, or earphones), network PCs, minicomputers, mainframe computers, distributed computing environments that include any of the above systems or devices, and the like. Such systems or devices may accept input from the user in any way, including from input devices such as a keyboard or pointing device, via gesture input, proximity input (such as by hovering), and/or via voice input.

The examples illustrated and described herein as well as examples not specifically described herein but within the scope of aspects of the disclosure constitute example means for coupling a housing mechanism to a printed circuit board and/or example means for coupling a fastening mechanism to a chassis.

The order of execution or performance of the operations in examples of the disclosure illustrated and described herein is not essential, unless otherwise specified. That is, the operations may be performed in any order, unless otherwise specified, and examples of the disclosure may include additional or fewer operations than those disclosed herein. For example, it is contemplated that executing or performing a particular operation before, contemporaneously with, or after another operation is within the scope of aspects of the disclosure.

When introducing elements of aspects of the disclosure or the examples thereof, the articles “a,” “an,” “the,” and “said” are intended to mean that there are one or more of the elements. The terms “comprising,” “including,” and “having” are intended to be inclusive and mean that there may be additional elements other than the listed elements. The phrase “one or more of the following: A, B, and C” means “at least one of A and/or at least one of B and/or at least one of C.”

Having described aspects of the disclosure in detail, it will be apparent that modifications and variations are possible without departing from the scope of aspects of the disclosure as defined in the appended claims. As various changes could be made in the above constructions, products, and methods without departing from the scope of aspects of the disclosure, it is intended that all matter contained in the above description and shown in the accompanying drawings shall be interpreted as illustrative and not in a limiting sense.

Alternatively or in addition to the other examples described herein, examples include any combination of the following:
a first body including a first head portion and a first shaft portion coupled to the first head portion;
a first shaft portion having an inner surface that defines a channel;
a second body including a second head portion and a second shaft portion coupled to the second head portion;
at least a part of the second shaft portion positionable within the channel;
the outer surface of the second shaft portion sized to enable the second shaft portion to expand radially or move laterally within the channel;
the first shaft portion having an outer surface that has a first diameter;
the second head portion having an outer surface that has a second diameter less than or equal to the first diameter;
the first body including a shoulder portion;
the first body including one or more projection members;
the first shaft portion having a first end section coupled to the first head portion and a second end section opposite the first end section;
the second end section including a chamfer;
the second body including a shoulder portion between the second head portion and the second shaft portion;
an outer surface of the second shaft portion extending substantially parallel to the inner surface of the first shaft portion;
a printed circuit board having an upper surface, a lower surface, and an inner surface that defines an opening extending between the upper surface and the lower surface;
a housing mechanism including a shaft portion that has an upper surface and an inner surface that defines a channel;
the housing mechanism coupleable to the lower surface of the printed circuit board such that the shaft portion extends at least partially through the opening;
a fastening mechanism including a head portion and a shaft portion;
the fastening mechanism head portion configured to engage the upper surface of the housing mechanism shaft portion such that at least a part of the fastening mechanism shaft portion extends through the channel;
the fastening mechanism shaft portion sized to expand radially or move laterally within the channel;
the housing mechanism including a housing mechanism head portion that has an upper surface;
the housing mechanism coupleable to the lower surface of the printed circuit board such that the upper surface of the housing mechanism head portion extends substantially parallel to the lower surface of the printed circuit board;
the housing mechanism shaft portion having an outer surface having a first diameter;
the fastening mechanism head portion having an outer surface that has a second diameter less than or equal to the first diameter;
the housing mechanism including a shoulder portion;
the housing mechanism including a housing mechanism head portion;
the housing mechanism shaft portion having an outer surface and one or more projection members extending radially outward from the outer surface;
the housing mechanism shaft portion having a first end section coupled to the housing mechanism head portion and a second end section including a chamfer;
the fastening mechanism head portion \configured to engage the upper surface of the housing mechanism shaft portion such that an upper surface of the fastening mechanism head portion is below or flush with the upper surface of the printed circuit board;
the fastening mechanism including a fastening mechanism shoulder portion between the fastening mechanism head portion and the fastening mechanism shaft portion;
the fastening mechanism head portion configured to engage the upper surface of the housing mechanism shaft portion such that an outer surface of the fastening mechanism shaft portion extends substantially parallel to the inner surface of the housing mechanism shaft portion;
coupling a housing mechanism to a lower surface of the printed circuit board such that a shaft portion of the housing mechanism extends at least partially through an opening defined in the printed circuit board;
the housing mechanism shaft portion having an upper surface and an inner surface that defines a channel;
coupling a fastening mechanism to the article such that a head portion of the fastening mechanism engages the upper surface of the housing mechanism shaft portion and at least a part of a shaft portion of the fastening mechanism extends through the channel;
the fastening mechanism shaft portion sized to expand radially or move laterally within the channel;
positioning the housing mechanism such that an upper surface of a head portion of the housing mechanism extends substantially parallel to the lower surface of the printed circuit board;
soldering, using a soldering material, the housing mechanism to the lower surface of the printed circuit board such that at least a portion of the soldering material is within a cavity at least partially defined by a chamfer of the housing mechanism shaft portion and an inner surface of the printed circuit board;
positioning the fastening mechanism such that a shoulder portion of the fastening mechanism engages a shoulder portion of the housing mechanism;
positioning the fastening mechanism such that an upper surface of a head portion of the fastening mechanism is below or flush with the upper surface of the printed circuit board; and
positioning the fastening mechanism such that an outer surface of the fastening mechanism shaft portion extends substantially parallel to the inner surface of the housing mechanism shaft portion.

While the aspects of the disclosure have been described in terms of various examples with their associated operations, a person skilled in the art would appreciate that a combination of operations from any number of different examples is also within scope of the aspects of the disclosure.

What is claimed is:

1. A coupling mechanism comprising:
a first body comprising a first head portion and a first shaft portion coupled to the first head portion, the first shaft portion having an inner surface that defines a channel; and
a second body comprising a second head portion and a second shaft portion coupled to the second head portion, at least a part of the second shaft portion positionable within the channel, the outer surface of the second shaft portion sized to enable the second shaft portion to expand radially or move laterally within the channel when the part of the second shaft portion is positioned within the channel.

2. The coupling mechanism of claim 2, wherein the first shaft portion has an outer surface having a first diameter, and the second head portion has an outer surface having a second diameter less than or equal to the first diameter.

3. The coupling mechanism of claim 2, wherein the first body comprises a shoulder portion.

4. The coupling mechanism of claim 2, wherein the first shaft portion has an outer surface and one or more projection members extending radially outward from the outer surface.

5. The coupling mechanism of claim 2, wherein the second body comprises a shoulder portion between the second head portion and the second shaft portion.

6. The coupling mechanism of claim 2, wherein an outer surface of the second shaft portion extends substantially parallel to the inner surface of the first shaft portion when the part of the second shaft portion is positioned within the channel.

7. A system comprising:
a printed circuit board having an upper surface, a lower surface, and an inner surface that defines an opening extending between the upper surface and the lower surface;
a housing mechanism comprising a shaft portion that has an upper surface and an inner surface that defines a channel, the housing mechanism coupleable to the lower surface of the printed circuit board such that the shaft portion extends at least partially through the opening when the housing mechanism is coupled to the lower surface of the printed circuit board; and
a fastening mechanism comprising a head portion and a shaft portion, the fastening mechanism head portion configured to engage the upper surface of the housing mechanism shaft portion such that at least a part of the fastening mechanism shaft portion extends through the channel when the fastening mechanism head portion engages the upper surface of the housing mechanism shaft portion, the fastening mechanism shaft portion sized to expand radially or move laterally within the channel when at least the part of the fastening mechanism shaft portion extends through the channel.

8. The system of claim 7, wherein the housing mechanism comprises a housing mechanism head portion that has an upper surface, the housing mechanism coupleable to the lower surface of the printed circuit board such that the upper surface of the housing mechanism head portion extends substantially parallel to the lower surface of the printed circuit board.

9. The system of claim 7, wherein the housing mechanism shaft portion has an outer surface having a first diameter, and the fastening mechanism head portion has an outer surface having a second diameter less than or equal to the first diameter.

10. The system of claim 7, wherein the housing mechanism comprises a shoulder portion.

11. The system of claim 7, wherein the housing mechanism comprises a housing mechanism head portion, the housing mechanism shaft portion having an outer surface and one or more projection members extending radially outward from the outer surface.

12. The system of claim 7, wherein the fastening mechanism head portion is configured to engage the upper surface of the housing mechanism shaft portion such that an upper surface of the fastening mechanism head portion is below or flush with the upper surface of the printed circuit board.

13. The system of claim 7, wherein the fastening mechanism comprises a fastening mechanism shoulder portion between the fastening mechanism head portion and the fastening mechanism shaft portion.

14. The system of claim 7, wherein the fastening mechanism head portion is configured to engage the upper surface of the housing mechanism shaft portion such that an outer surface of the fastening mechanism shaft portion extends substantially parallel to the inner surface of the housing mechanism shaft portion.

15. A method of coupling a printed circuit board to an article, the method comprising:
coupling a housing mechanism to a lower surface of the printed circuit board such that a shaft portion of the housing mechanism extends at least partially through an opening defined in the printed circuit board, the housing mechanism shaft portion having an upper surface and an inner surface that defines a channel; and
coupling a fastening mechanism to the article such that a head portion of the fastening mechanism engages the upper surface of the housing mechanism shaft portion and at least a part of a shaft portion of the fastening mechanism extends through the channel, the fastening mechanism shaft portion sized to expand radially or move laterally within the channel.

16. The method of claim 15, wherein coupling a housing mechanism to a lower surface of the printed circuit board comprises positioning the housing mechanism such that an upper surface of a head portion of the housing mechanism extends substantially parallel to the lower surface of the printed circuit board.

17. The method of claim 15, wherein coupling a housing mechanism to a lower surface of the printed circuit board comprises soldering, using a soldering material, the housing mechanism to the lower surface of the printed circuit board such that at least a portion of the soldering material is within a cavity at least partially defined by the housing mechanism shaft portion and an inner surface of the printed circuit board.

18. The method of claim 15, wherein coupling a fastening mechanism to the article comprises positioning the fastening mechanism such that a shoulder portion of the fastening mechanism engages a shoulder portion of the housing mechanism.

19. The method of claim 15, wherein coupling a fastening mechanism to the article comprises positioning the fastening mechanism such that an upper surface of a head portion of the fastening mechanism is below or flush with the upper surface of the printed circuit board.

20. The method of claim 15, wherein coupling a fastening mechanism to the article comprises positioning the fastening mechanism such that an outer surface of the fastening mechanism shaft portion extends substantially parallel to the inner surface of the housing mechanism shaft portion.
